(19) United States
(12) Patent Application Publication
(10) Pub. No.: US 2022/0214563 A1
(43) Pub. Date: Jul. 7, 2022

(54) SPECTACLE LENS DESIGN SYSTEM, SPECTACLE LENS DESIGN METHOD, AND SPECTACLE LENS DESIGN PROGRAM

(71) Applicant: HOYA LENS THAILAND LTD., Pathumthani (TH)

(72) Inventors: Shinichiro TAGUCHI, Tokyo (JP); Takao TANAKA, Tokyo (JP); Keima SAKATA, Tokyo (JP); Tadashi KAGA, Tokyo (JP)

(73) Assignee: HOYA LENS THAILAND LTD., Pathumthani (TH)

(21) Appl. No.: 17/610,299

(22) PCT Filed: Aug. 21, 2020
(86) PCT No.: PCT/JP2020/031594

§ 371 Date: Nov. 10, 2021

(30) Foreign Application Priority Data
Sep. 27, 2019 (JP) 2019-176929

(51) Int. Cl. G02C 7/02

(52) U.S. Cl. CPC G02C 7/028; G02B 1/14; G02C 7/027

(57) ABSTRACT

A spectacle lens design system capable of suppressing deformation during finishing processing. The system (LDS100) is designed for a spectacle lens, wherein the spectacle lens design system comprises: a prescription data acquisition part 110 to acquire prescription data which includes prescribed power information, and designated lens thickness information relating to finishing processing information regarding finishing processing after shaping of a spectacle lens; an optical surface calculation part 122 to calculate an optical surface shape based on the prescribed power information of the prescription data, thereby generating optical surface shape data; an appropriate lens thickness information generation part 124 to generate appropriate lens thickness information regarding a lens thickness appropriate for performing the finishing processing, based on the finishing processing information of the prescription data; and a thickness calculation and shape adjustment part 127 to adjust lens shape data based on the optical surface shape data and the lens thickness information.

### TECHNICAL FIELD

The present disclosure relates to a spectacle lens design system, a spectacle lens design method, and a spectacle lens design program.

### BACKGROUND ART

Heretofore, a spectacle lens manufacturing plant has been equipped with a lab management system (hereinafter refereed to as “LMS”) through which an order for spectacle lens manufacturing is received from an optician's store, and a processing apparatus and a manufacturing process in the plant are controlled and managed, based on information about the received order (see, for example, the below-mentioned Patent Document 1).

Further, it has been a common practice that a spectacle lens design vendor provides a lens design system (hereinafter refereed to as “LDS”) to a spectacle lens manufacturer, and then the spectacle lens manufacturer causes the LDS to execute calculation on based on prescription data, thereby designing and manufacturing a spectacle lens. For example, a calculation process in the LDS is performed on a server of the manufacturing plant or on a web service such as a terminal, based on prescription data input from a terminal installed in the optician's store, and a result of the calculation process in the LDS is output to the LMS.

### CITATION LIST

### Patent Document

Patent Document 1: JP-A 2014-085574

### SUMMARY OF DISCLOSURE

### Technical Problem

Here, after being processed into a shape having a given optical function, a spectacle lens is subjected to processing such as dyeing or hard coating. In this case, if a lens thickness such as a central thickness or an edge thickness designated in the prescription data is insufficient, the spectacle lens is likely to deform during a process in which high temperature is applied to the lens, such as annealing, in finishing processing. Further, in a case where the lens thickness such as the central thickness or the edge thickness is not designated in the prescription data input from the terminal, there is a possibility of failing to carry out the calculation.

The present disclosure has been made in view of the above problem, and an object thereof is to provide a spectacle lens design system, method and program which are capable of suppressing deformation during finishing processing.

### Solution to Technical Problem

According to one aspect of the present disclosure, there is provided a spectacle lens design system for designing a spectacle lens. The spectacle lens design system comprises: a prescription data acquisition part to acquire prescription data which includes prescribed power information, and designated lens thickness information relating to finishing processing information regarding finishing processing after shaping of a spectacle lens; an optical surface calculation part to calculate an optical surface shape based on the prescribed power information of the prescription data, thereby generating optical surface shape data; an appropriate lens thickness information generation part to generate appropriate lens thickness information regarding a lens thickness appropriate for performing the finishing processing, based on the finishing processing information of the prescription data; and a shape adjustment part to adjust a lens shape based on the optical surface shape data and the appropriate lens thickness information, thereby generating lens shape data.

According to another aspect of the present disclosure, there is provided a spectacle lens design method for designing a spectacle lens. The spectacle lens design method comprises: a prescription data acquisition step of acquiring prescription data which includes prescribed power information, and designated lens thickness information relating to finishing processing information regarding finishing processing after shaping of a spectacle lens; an optical surface calculation step of calculating an optical surface shape based on the prescribed power information of the prescription data, thereby generating optical surface shape data; an appropriate lens thickness information generation step of generating appropriate lens thickness information regarding a lens thickness appropriate for performing the finishing processing, based on the finishing processing information of the prescription data; and a shape adjustment step of adjusting a lens shape based on the optical surface shape data and the appropriate lens thickness information, thereby generating lens shape data.

### Effect of Disclosure

The present disclosure can provide a spectacle lens design system, method and program which are capable of suppressing deformation during finishing processing.

### BRIEF DESCRIPTION OF DRAWINGS

FIG. 1 is a block diagram showing the configuration of a spectacle lens ordering and processing system according to one embodiment of the present disclosure.

FIG. 2 is a block diagram showing a hardware configuration of a LDS in the spectacle lens ordering and processing system illustrated in FIG. 1.

FIG. 3 is a block diagram showing the configuration of function parts of the LDS in the spectacle lens ordering and processing system illustrated in FIG. 1.

FIG. 4 illustrates a dyeing table stored in a finishing processing and lens thickness database.

FIG. 5 illustrates a hard coating table stored in the finishing processing and lens thickness database.

FIG. 6 illustrates a functional film table stored in the finishing processing and lens thickness database.

FIG. 7 illustrates a frame table stored in the finishing processing and lens thickness database.

FIG. 8 is a block diagram showing the configurations of a LMS and a processing machine in the spectacle lens ordering and processing system illustrated in FIG. 1.

FIG. 9 is a flowchart showing one example of a process flow of operation of the spectacle lens ordering and processing system illustrated in FIG. 1.

FIG. 10 is a flowchart showing a detailed flow of a shape optimization calculation step in the flowchart illustrated in FIG. 9.

### DESCRIPTION OF EMBODIMENTS

A spectacle lens design system according to one embodiment of the present disclosure will now be described based on the drawings.

### 1. Spectacle Lens Ordering and Processing System

A spectacle lens ordering and processing system 1 will be described below.

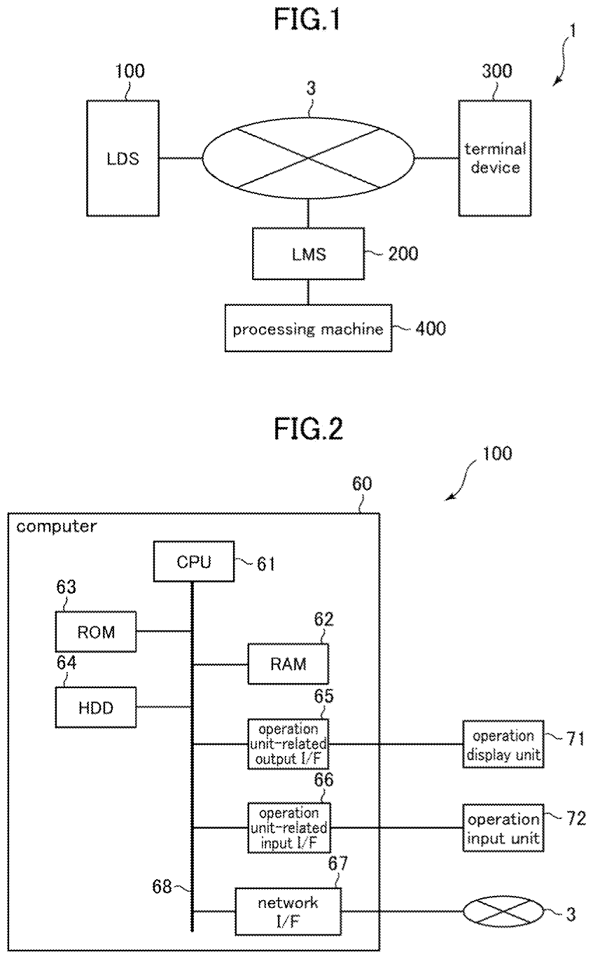

FIG. 1 is a block diagram showing the configuration of the spectacle lens ordering and processing system according to one embodiment of the present disclosure. As shown in FIG. 1, the spectacle lens ordering and processing system 1 comprises a spectacle lens design system (hereinafter referred to as “LDS”) 100, a lab management system (hereinafter referred to as “LMS”) 200, a terminal device 300, and a processing machine 400.

The LDS 100, the LMS 200 and the terminal device 300 are communicably connected together via a network 3. The LMS 200 and the processing machine 400 are connected to each other via a LAN (Local Area Network). Examples of the network 3 include communication networks such as the Internet, intranets, LANs, and phone lines, based on a general-purpose protocol such as TCP/IP.

The LDS 100 may be installed inside a plant of a spectacle lens manufacturer, or may be installed outside the plant. The LMS 200 and the processing machine 400 are installed in, e.g., the plant of the spectacle lens manufacturer. The terminal device 300 is installed in, e.g., an optician's store. The terminal device 300 is composed of, e.g., a computer having a CPU, a RAM and a HDD, wherein the CPU is configured to execute each processing according to a program recorded in the HDD, using the RAM as a work area. The terminal device 300 is configured to accept an input of prescription data created at the optician's store through examination for a buyer of eyeglasses.

### 2. Example of Hardware Configuration of LDS

A hardware configuration of the LDS 100 will be described below.

FIG. 2 is a block diagram showing the hardware configuration of the LDS in the spectacle lens ordering and processing system illustrated in FIG. 1. As one example, the LDS 100 comprises a computer 60 for controlling operations of the entire LDS 100, an operation display unit 71, and an operation input unit 72, as shown in FIG. 2.

The computer 60 comprises a CPU 61, a RAM 62, a ROM 63, a HDD 64, an operation unit-related output I/F 65, an operation unit-related input I/F 66, and a network I/F 67.

The CPU (Central Processing Unit) 61 is configured to execute various programs. The CPU 61 is configured to activate a system based on a boot program stored in the ROM (Read Only Memory) 63. Further, the CPU 61 is configured to read out a control program stored in the HDD (Hard Disk Drive) 64, and execute given processing, using the RAM (Random Access Memory) 62 as a work area.

The HDD 64 stores therein various control programs, and finishing processing and lens thickness data. Further, data acquired from outside the device via the network I/F 67 and a result of calculation by the control programs will be stored in the HDD 64.

The operation unit-related output I/F 65 is configured to perform data output communication control to the operation display unit 71. The operation unit-related input I/F 66 is configured to perform data input communication control from the operation input unit 72. The network I/F 67 is connected to the network 3, and configured to control input and output of information via the network 3. The above components 61 to 67 are arranged on a system bus 68.

The operation display unit 71 is a display interface for a user, wherein it comprises a display device such as a LCD (Liquid Crystal Display) or a LED (Light Emitting Diode). The operation input unit 72 is an interface allowing the user to input instructions therethrough, wherein it comprised an input device such as a touch panel or a hardware key.

The LDS 100 can be realized by a computer 60, such as a server computer or a personal computer, connected to the operation display unit 71 and the operation input unit 72.

The function of each unit of the LDS 100 can be realized by causing the CPU 61 to read out the control programs stored in the HDD 64 to the RAM 62 and execute the control programs. It should be noted that the configuration of any part which is not related to the essence of the present disclosure is omitted and unillustrated.

### 3. Example of Configuration of Function Parts of LDS

An examples of the configuration of function parts of the LDS 100 will be described below.

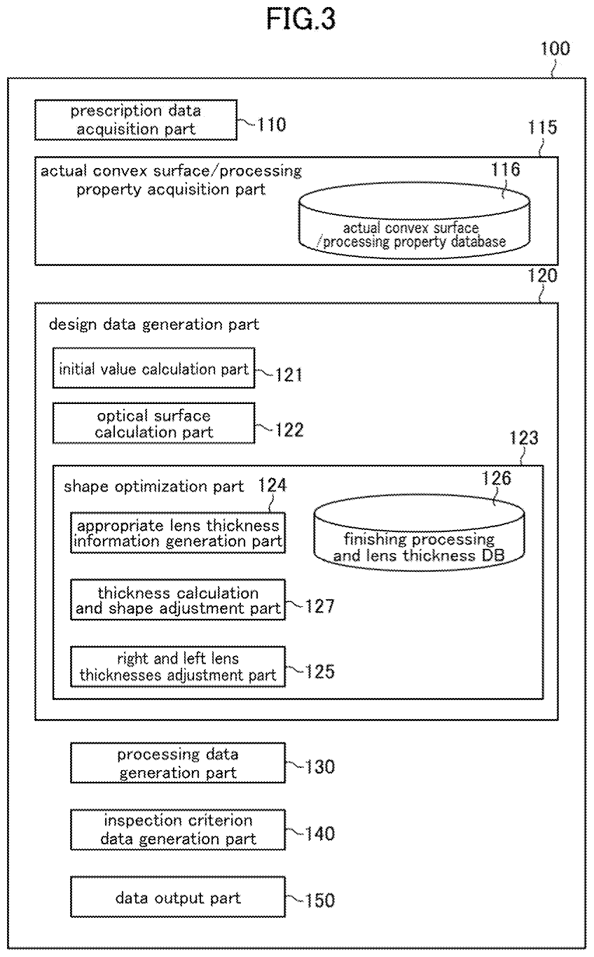

FIG. 3 is a block diagram showing the configuration of function parts of the LDS in the spectacle lens ordering and processing system illustrated in FIG. 1. The function parts illustrated in FIG. 3 are realized on the LDS 100 by causing the CPU 61 to execute the programs stored in the ROM 63 or the HDD 64 of the LDS 100, and cooperate with the HDD 64, the operation unit-related output I/F 65, the operation unit-related input I/F 66 and the network I/F. It should be noted here that FIG. 3 shows the configuration of only a part of the function parts particularly related to the description of this embodiment.

As shown in FIG. 3, the LDS 100 comprises: a prescription data acquisition part 110; an actual convex surface/processing property acquisition part 115; a design data generation part 120; a processing data generation part 130; an inspection criterion data generation part 140; and a data output part 150.

### Prescription Data Acquisition Part

The prescription data acquisition part 110 is configured to acquire prescription data of a spectacle lens, input to the terminal device 300.

The prescription data is data for prescribing the spectacle lens, wherein it includes: prescribed power information such as spherical power (also called “S power”), cylindrical power (also called “C power”), astigmatic axial direction (AX), and add power (ADD); item information such as item name; layout information such as pupillary distance (PD) and eye point; lens-worn state information; lens substrate information; finishing processing information; and designated lens thickness information.

Here, the lens substrate information is information about the type of plastic used as a substrate of a semifinished lens usable for a spectacle lens.

The finishing processing information is information about finishing processing to be performed for a lens after lens shaping. The term “after lens shaping” here means after shaping for forming a lens blank into a shape having desired optical performance. In this embodiment, the finishing processing information includes: dyeing information regarding the type of lens dyeing; hard coating information regarding the type of hard coating; functional film information regarding the type of functional film; and frame information regarding the type of frame. It should be noted here that the finishing processing information may include any one of the dyeing information, the hard coating information, the functional film information and the frame information. Additionally, an AR (Anti Reflection) coating information regarding an AR coating may be included therein.

The dyeing information includes dyeing material information regarding a designated color or colorant, and dyeing method information regarding a dyeing method such as immersion, pressurization or ink-jet.

The hard coating information includes hard coating material information regarding the type of hard coating material to be coated on a lens so as to add a surface hardness, and coating method information regarding a coating method such as immersion or spin coating.

The functional film information includes functional film type information regarding the type of functional film for adding photochromic performance or polarization performance to a lens, and generation method information regarding a generation method for a functional film.

The frame information includes frame information regarding the type of frame such as a plastic frame and a metal frame, and processing method information regarding a processing method of processing a spectacle lens in conformity to the type of frame.

The designated lens thickness information is information regarding a lens thickness input to the terminal device 300 of the optician's store. In this embodiment, the designated lens thickness information includes: a minimum designated central thickness min CT₀ which is a minimum value of a central thickness at the center of a lens designated by the terminal device 300; a minimum designated edge thickness min ET₀ which is a minimum value of an edge thickness of the lens; and a minimum designated total thickness min CTET₀ which is a minimum value of the total of the central thickness and the edge thickness. It should be noted here that the minimum designated total thickness min CTET₀ does not have to be included.

### Actual Convex Surface/Processing Property Acquisition Part

The actual convex surface/processing property acquisition part 115 has an actual convex surface/processing property database 116. In the actual convex surface/processing property database 116, actual convex surface data of each semifinished lens, and processing property data regarding a processing property of each semifinished lens, are recorded.

The term “actual convex surface” means an actual surface shape of a semifinished lens, more specifically, an actually measured shape of a convex surface of the semifinished lens, or the shape of a convex surface model statistically derived from a result of measurement of the semifinished lens. This actual convex surface data is used in the after-mentioned inspection data generation processing.

The processing property includes: a phenomenon that, in blocking processing for bonding a fixing jig to a convex surface of a semifinished lens with an alloy (low-melting point alloy), to be performed prior to cutting and grinding of the semifinished lens, the shape of the convex surface of the semifinished lens changes due to a stress generated during cooling of the alloy; or a phenomenon that a grinding amount or machining allowance depending on a grinding method becomes uneven. The processing property is used in the after-mentioned processing data generation processing.

The actual convex surface/processing property acquisition part 115 is configured to select a semifinished lens to be used, based on the prescription data.

### Design Data Generation Part

The design data generation part 120 is configured to generate design data based on the prescription data.

The design data generation part 120 comprises an initial value calculation part 121, an optical surface calculation part 122, and a shape optimization part 123.

### Initial Value Calculation Part

The initial value calculation part 121 is configured to calculate an initial value necessary to perform optimization in terms of optical performance and lens shape, based on the prescription data. Examples of the initial value include a basic distribution of optical performance. The initial value calculation part 121 is also configured to derive parameters necessary for optical calculation of a tilt angle of a lens itself and a lens angle (face form angle), from the layout information and the lens-worn state information.

### Optical Surface Calculation Part

The optical surface calculation part 122 is configured to perform convergence calculation for an optimal optical surface, from a basic distribution of determined optical performance, while taking into consideration the convex surface shape, the lens-worn state, etc., to generate optical surface shape data.

### Shape Optimization Part

The shape optimization part 123 comprises an appropriate lens thickness information generation part 124, a right and left lens thicknesses adjustment part 125, a thickness calculation and shape adjustment part 127, and a finishing processing and lens thickness database (DB) 126.

### Finishing Processing and Lens Thickness Database

The finishing processing and lens thickness database 126 records therein finishing processing and lens thickness data in which finishing processing of the lens and minimum lens thickness information indicative of a minimum value of the lens thickness are associated with each other. In this embodiment, the finishing processing and lens thickness data is stored in the form of a dyeing table, a hard coating table, a functional film table, and a frame table.

### Dyeing Table

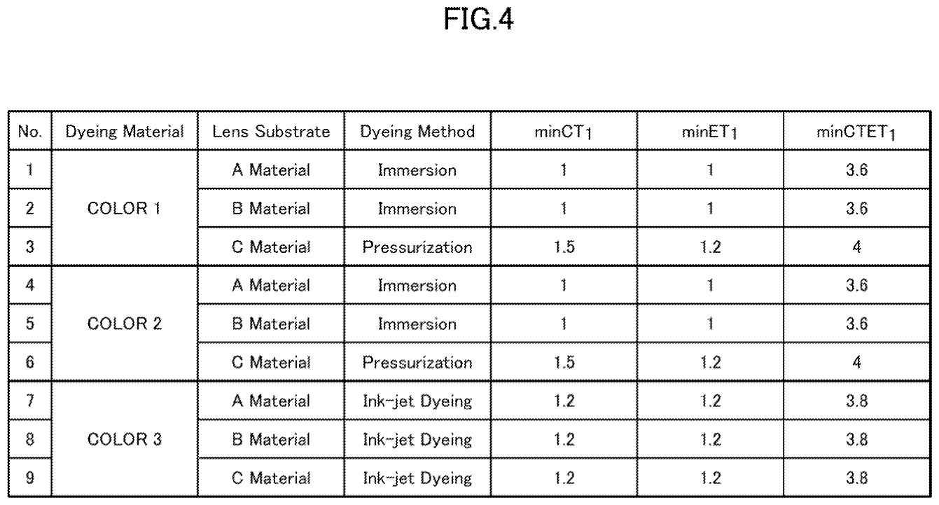

FIG. 4 illustrates the dyeing table stored in the finishing processing and lens thickness database. A dyeing process is a process of immersing a lens in a dyeing tank containing a colorant or dye to impregnate the lens with the dye. A dyeing duration varies depending on the type of dyeing, and, in some cases, a pressurized dyeing tank is used for a lens made of a high refractive index material which is less likely to be impregnated. During dyeing, a lens is held by a dedicated jig and tool. Due to a stress at that time, the lens is likely to deform. Further, after the dyeing, the lens is dried in an electric furnace or the like so as to prevent water from remaining in the lens. In this process, the lens is also likely to deform into an unintended shape. There is an alternative method of dying a lens by means of sublimation without using any dyeing tank. In this case, however, the lens is exposed to high temperatures due to the sublimation, possibly resulting in deformation thereof. Therefore, as shown in FIG. 4, in the dyeing table, a minimum central thickness min CT₁ which is an appropriate minimum value of the central thickness, a minimum edge thickness min ET₁ which is an appropriate minimum value of the edge thickness, and a minimum total thickness min CTET₁ which is an appropriate minimum value of the total of the central thickness and the edge thickness, are set, correspondingly to each of a plurality of combinations of the type of dyeing material, the type of lens substrate, and the type of dyeing method. The minimum central thickness min CT₁, the minimum edge thickness min ET₁, and the minimum total thickness min CTET₁ are values which can prevent deformation or the like from occurring in the lens even after undergoing dyeing, so as to ensure given lens quality, and can be determined, for example, by actually subjecting a plurality of test pieces different in the central thickness and the edge thickness to dyeing under conditions in which the type of dyeing material, the type of lens substrate and the type of dyeing method are variously changed and combined. For example, in a case where the dyeing material, the lens substrate and the dyeing method are, respectively, “COLOR 2”, “B Material” and “Immersion”, the dyeing type corresponds to No. 5, wherein the minimum central thickness min CT₁, the minimum edge thickness min ET₁ and the minimum total thickness min CTET₁ are, respectively, 1 mm, 1 mm, and 3.6 mm.

### Hard Coating Table

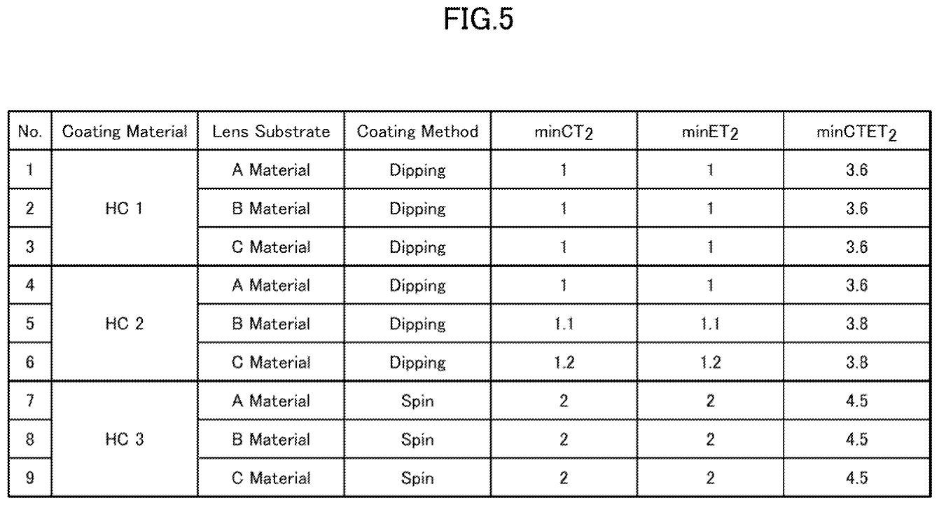

FIG. 5 illustrates the hard coating table stored in the finishing processing and lens thickness database. A method of forming a hard coating for protection from scratches includes a method which comprises applying a coating material onto the surface of a lens by spin coating, and subjecting the coating material on the lens to UV curing or thermal curing, and a method which comprises immersing a lens in a special silicon solution, and curing the solution on the lens through a curing process of applying heat thereto. However, in the method using UV curing or thermal curing, the lens is likely to deform due to insufficiency of the strength of the lens with respect to a stress generated by shrinkage during curing, and, in the method of performing curing through the curing process, the lens is also likely to deform due to heat during the curing process. Therefore, as shown in FIG. 5, in the hard coating table, a minimum central thickness min CT₂ which is an appropriate minimum value of the central thickness, a minimum edge thickness min ET₂ which is an appropriate minimum value of the edge thickness, and a minimum total thickness min CTET₂ which is an appropriate minimum value of the total of the central thickness and the edge thickness, are set, correspondingly to each of a plurality of combinations of the type of coating material, the type of lens substrate, and the type of coating method. The minimum central thickness min CT₂, the minimum edge thickness min ET₂, and the minimum total thickness min CTET₂ are values which can prevent deformation or the like from occurring in the lens even after undergoing coating, so as to ensure given lens quality, and can be determined, for example, by actually subjecting a plurality of test pieces different in the central thickness and the edge thickness to hard coating under conditions in which the type of coating material, the type of lens substrate and the type of coating method are variously changed and combined. For example, in a case where the coating material, the lens substrate and the coating method are, respectively, “HC 3”, “B Material” and “Spin”, the coating type corresponds to No. 8, wherein the minimum central thickness min CT₂, the minimum edge thickness min ET₂ and the minimum total thickness min CTET₂ are, respectively, 2 mm, 2 mm, and 4.5 mm.

### Functional Film Table

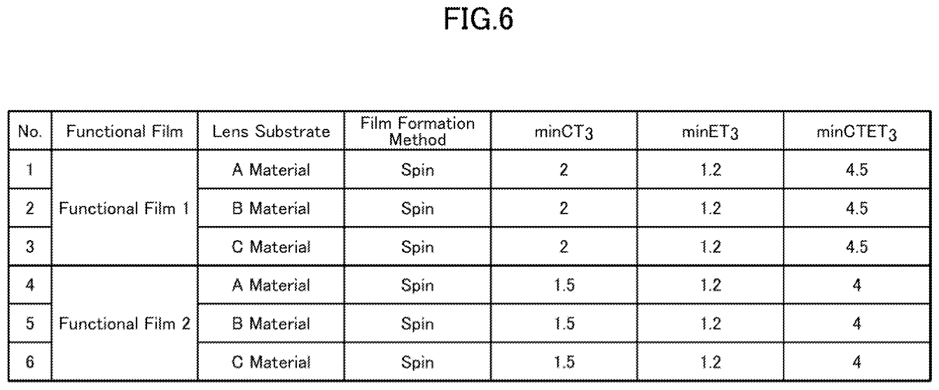

FIG. 6 illustrates the functional film table stored in the finishing processing and lens thickness database. A functional film having photochromic performance and others is formed by applying a solution onto an pre-grinding or post-grinding surface of a lens by spin coating, and subjecting the solution on the lens to UV curing or thermal curing. In this case, however, the lens is likely to deform due to insufficiency of the strength of the lens with respect to a stress generated by shrinkage during curing. Therefore, as shown in FIG. 6, in the functional film table, a minimum central thickness min CT₃ which is an appropriate minimum value of the central thickness, a minimum edge thickness min ET₃ which is an appropriate minimum value of the edge thickness, and a minimum total thickness min CTET₃ which is an appropriate minimum value of the total of the central thickness and the edge thickness, are recorded, correspondingly to each of a plurality of combinations of the type of functional film, the type of lens substrate, and the type of film formation method. The minimum central thickness min CT₃, the minimum edge thickness min ET₃, and the minimum total thickness min CTET₃ are values which can prevent deformation or the like from occurring in the lens even after undergoing formation of the functional film, so as to ensure given lens quality, and can be determined, for example, by actually forming a plurality of functional films onto a plurality of test pieces different in the central thickness and the edge thickness, under conditions in which the type of functional film, the type of lens substrate and the type of film formation method are variously changed and combined. For example, in a case where the functional film, the lens substrate and the film formation method are, respectively, “Functional Film 1”, “B Material” and “Spin”, the functional film type corresponds to No. 2, wherein the minimum central thickness min CT₃, the minimum edge thickness min ET₃ and the minimum total thickness min CTET₃ are, respectively, 2 mm, 1.2 mm, and 4.5 mm.

### Frame Table

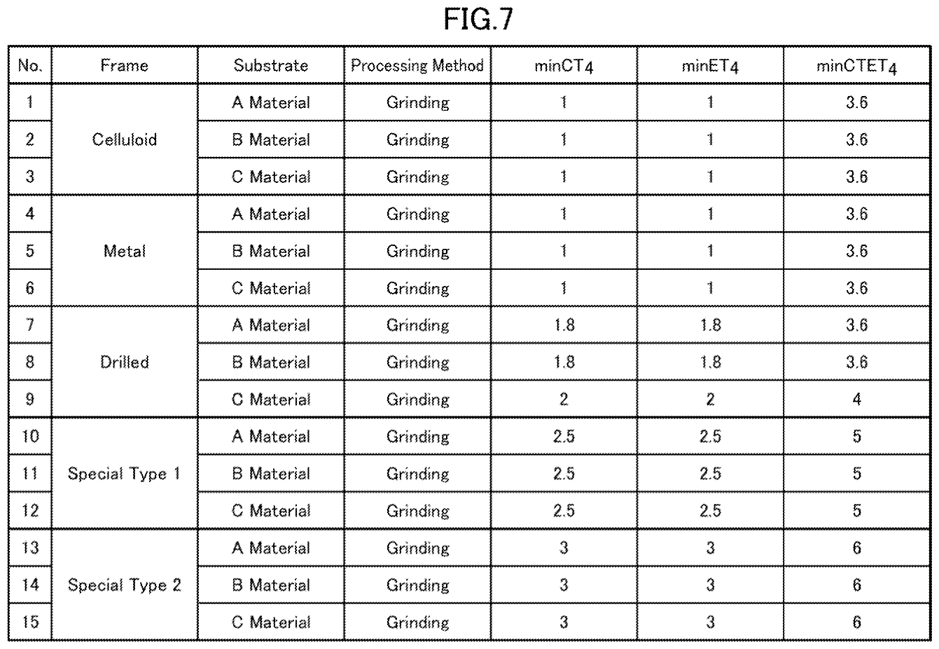

FIG. 7 illustrates the frame table stored in the finishing processing and lens thickness database. The type of eyeglasses frame includes a celluloid frame (plastic frame), a metal frame, a rimless frame, and a two-point frame. In the celluloid frame, the frame has a thickness, so that, even if a lens is thick to some extent, it is not noticeable in terms of appearance. In the metal frame or the rimless frame, it is often the case that the edge of a lens is visibly exposed, and thus the lens thickness is noticeable, so that it tends to seek thinness. In the two-point frame, holes are created in a lens, and a temple and a bridge of the frame are screwed to the lens through the holes. Thus, in order to ensure the strength of the lens so as to prevent breakage, it is necessary to ensure a certain lens thickness around each of the holes. In one type of rimless frame (the trade name “PINFEEL”), a hole is drilled to extend from the edge toward the center of a lens, for joining of a temple or a bridge, and the temple or the bridge is adhesively bonded to the lens through the hole (see FIGS. 1 and 2 of WO2006/046558). The lens thickness required for the joining is determined by the shape of the frame (lens). Further, in order to ensure the strength of the lens, it is necessary to ensure a certain lens thickness at the position of the special processing. The required lens thickness varies depending on lens materials. In another type of rimless frame (the trade name “AIRLIST”), a lens is subjected to special concavo-convex processing to form a particular cutout for joining of a temple or a bridge, and the temple or the bridge is adhesively bonded to the lens through the cutout (see FIG. 3 of WO2006/046558). The lens thickness required for the joining is determined by the shape of the frame (lens). Further, in order to ensure the strength of the lens, a certain lens thickness is ensured at the position of the special processing. The required lens thickness varies depending on lens materials. Considering the above, as shown in FIG. 7, in the frame table, a minimum central thickness min CT₄ which is an appropriate minimum value of the central thickness, a minimum edge thickness min ET₄ which is an appropriate minimum value of the edge thickness, and a minimum total thickness min CTET₄ which is an appropriate minimum value of the total of the central thickness and the edge thickness, are recorded, correspondingly to each of a plurality of combinations of the type of frame, the type of lens substrate, and the type of frame processing method. The minimum central thickness min CT₄, the minimum edge thickness min ET₄, and the minimum total thickness min CTET₄ are values which can prevent deformation or the like from occurring in the lens even after undergoing processing for mounting the frame, so as to ensure given lens quality, and can be determined, for example, by actually subjecting a plurality of test pieces different in the central thickness and the edge thickness to lens processing, under conditions in which the type of frame, the type of lens substrate and the type of frame processing method are variously changed and combined. For example, in a case where the frame, the lens substrate and the frame processing method are, respectively, “Metal”, “C Material” and “Grinding”, the frame type corresponds to No. 6, wherein the minimum central thickness min CT₄, the minimum edge thickness min ET₄ and the minimum total thickness min CTET₄ are, respectively, 1 mm, 1 mm, and 3.6 mm.

### Appropriate Lens Thickness Information Generation Part

The appropriate lens thickness information generation part 124 is configured to refer to the finishing processing and lens thickness database 126 to determine appropriate lens thickness information based on the lens substrate information and the finishing processing information included in the prescription data. The appropriate lens thickness information is information about a lens thickness which can prevent the occurrence of deformation and degradation in optical performance during finishing processing. In this embodiment, the appropriate lens thickness information includes: an appropriate minimum central thickness min CT_{A} regarding a minimum value of the central thickness of a lens; an appropriate minimum edge thickness min ET_{A} regarding a minimum value of the edge thickness of the lens; and an appropriate minimum total thickness min CTET_{A} regarding a minimum value of the total of the central thickness and the edge thickness of the lens. It should be noted that, although this embodiment has been described based on an example where the appropriate lens thickness information is determined based on the lens substrate information and the finishing processing information, the lens substrate information does not have to be used. Further, the appropriate lens thickness information does not have to include the appropriate minimum total thickness min CTET_{A}.

### Thickness Calculation and Shape Adjustment Part

The thickness calculation and shape adjustment part 127 is configured to perform lens thickness calculation and lens shape optimization calculation, based on the appropriate lens thickness information and the optical surface shape data, to generate lens thickness information, and lens shape data regarding shapes of right and left lenses.

### Right and Left Lens Thicknesses Adjustment Part

The right and left lens thicknesses adjustment part 125 is configured to calculate respective weights of right and left lenses, based on the lens substrate information, the optical surface shape data generated by the optical surface calculation part 122, and the designated lens thickness information. Specifically, the specific gravity of the lens substrate is identified from the lens substrate information. Then, respective volumes of the right and left lenses are computed based on design data about the right and left lens, and respective weights of the right and left lenses are calculated based on the specific gravity and the volumes. The right and left lens thicknesses adjustment part 125 is also configured to compute an additional lens thickness in conformity to a heavier one of the right and left lens.

### Processing Data Generation Part

The processing data generation part 130 is configured to generate processing data based on the design data.

The processing data is data for allowing a processing machine such as a blocker 410, a CG (Curve Generator) 420 and a grinding machine 430 to cut and grind a concave surface of a semifinished lens to form a finished lens.

### Inspection Criterion Data Generation Part

The inspection criterion data generation part 140 is configured to generate data (inspection criterion data) serving as a criterion to be used when the aberration or the like of a lens processed based on the processing data (finished lens) is inspected by an inspection device 450 provided in the processing machine 400 of the LMS 200.

### Data Output Part

The data output part 150 is configured to output, to the LMS 200, data produced by the design data generation part 120, the processing data generation part 130 and the inspection criterion data generation part 140.

### 4. Configurations of LMS and Processing Machine

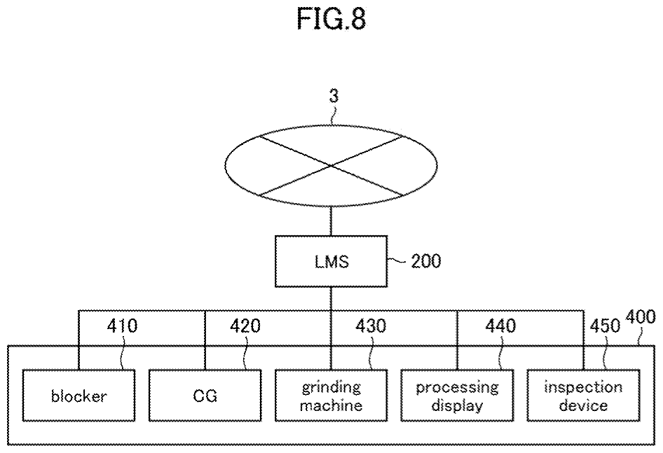

Next, the configurations of the LMS 200 and the processing machine 400 will be described. FIG. 8 is a block diagram showing the configurations of the LMS and the processing machine in the spectacle lens ordering and processing system illustrated in FIG. 1. As shown in FIG. 8, similar to the LDS, the LMS 200 comprises a computer for controlling operations of the entire LMS, an operation display unit, and an operation input unit. The computer comprises a CPU, a RAM, a ROM, a HDD, an operation unit-related output I/F, an operation unit-related input I/F, and a network I/F. Each processing by the LMS 200 is realized by causing the CPU to read out control programs stored in the HDD and execute the control programs,

The processing machine 400 comprises a blocker 410, a CG (Curve Generator) 420, a grinding machine 430, a processing display 440, and an inspection device 450. Operations of the blocker 410, the CG 420, the grinding machine 430, the processing display 440 and the inspection device 450 are controlled by the LMS 200. A grinding process is performed in the blocker 410, the CG 420, the grinding machine 430 and the processing display 440, and an inspection process is performed in the inspection device 450.

### Blocker

The blocker 410 is configured to fix a semifinished lens to a fixing jig, prior to grinding.

### CG

The CG 420 is configured to cut a concave surface of the semifinished lens into a given shape.

### Grinding Machine

The grinding machine 430 is configured to grind the cut surface to remove a step or the like as a processing mark formed on an optical surface of the lens by the CG 420, and further grind the lens surface until it becomes a minor surface.

### Processing Display

The processing display 440 is composed of, e.g., a liquid crystal display, wherein it is provided in, e.g., a processing chamber in which dyeing, hard coating or the like is performed, and configured to display the content of finishing processing necessary for a shaped lens.

### Inspection Device

The inspection device 450 is configured to inspect the aberration of a finished lens, based on aberration inspection data generated by the LDS 100.

### 5. Process Flow of Spectacle Lens Ordering and Processing

A process flow of operation of the spectacle lens ordering and processing system 1 will be described below.

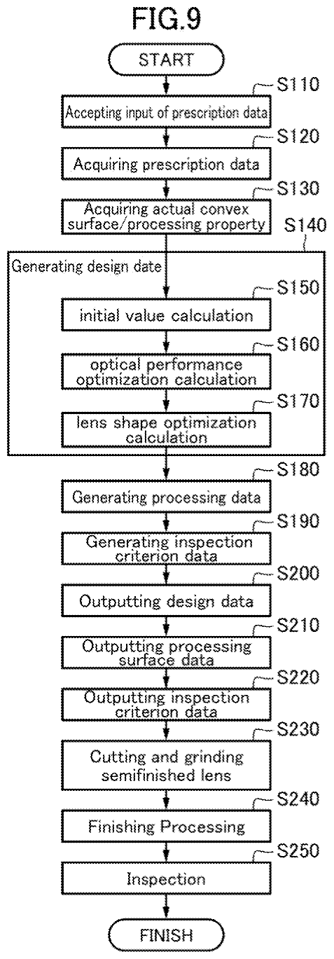

FIG. 9 is a flowchart showing one example of the process flow of operation of the spectacle lens ordering and processing system illustrated in FIG. 1.

### Acceptance of Input of Prescription Data

First of all, the terminal device 300 accepts an input of the prescription data of a spectacle lens to accept an order (S110). The prescription data includes: the prescribed power information such as spherical power (S power), cylindrical power (C power), astigmatic axial direction (AX) and add power (ADD); the item information such as item name; the layout information such as pupillary distance (PD) and eye point; the lens-worn state information; the lens substrate information; the finishing processing information; and the designated lens thickness information. Here, the designated lens thickness information includes the minimum designated central thickness min CT₀, the minimum designated edge thickness min ET₀, and the minimum designated total thickness min CTET₀.

### Acquisition of Prescription Data

The prescription data acquisition part 110 of the LDS 100 acquires the prescription data of the lens (S120: prescription data acquisition step). Subsequently, a semifinished lens to be used is selected based on the prescription data.

### Acquisition of Actual Convex Surface/Processing Property

The actual convex surface/processing property acquisition part 115 refers to the actual convex surface/processing property database 116 to select a semifinished lens based on the prescription data, and acquire data about an actual convex surface and a processing property of the selected semifinished lens (S130).

### Generation of Design Data

The design data generation part 120 generates design data regarding a lens shape, based on the prescription data (S140).

The design data is data including: optical surface shape data and lens thickness information (lens shape data) generated based on the prescription data; and additional lens thickness information, and is generated by performing initial value calculation (S150), optical performance optimization calculation (S160), and shape optimization calculation (S170).

### Initial Value Calculation

Firstly, the initial value calculation part 121 of the design data generation part 120 calculates, based on the prescription data, an initial value necessary to perform optimization in terms of optical performance and lens shape (S150). Further, the initial value calculation part 121 derives parameters necessary for optical calculation of a tilt angle of the lens itself and a lens angle (face form angle), from the layout information and the lens-worn state information. In a case where there is no such necessary information when acquiring the prescription data, a preliminarily defined default value is used as an alternative therefor. The layout information means information to be used for adjusting the optical center of the spectacle lens to coincide with the position of the pupil of a wearer, and indicates the position of a fitting point (eye point) on the basis of a geometric center of a frame (frame center). Further, the initial value calculation part 121 determines a basic distribution of optical performance, from the item information and the prescribed power information.

### Optical Performance Optimization Calculation

Then, the optical surface calculation part 122 of the design data generation part 120 performs convergence calculation for an optimal optical surface, from the determined basic distribution of determined optical performance, while taking into consideration the convex surface shape, the lens-worn state, etc., to generate optical surface shape data (S160: optical surface calculation step).

### Shape Optimization Calculation

Then, the shape optimization part 123 of the design data generation part 120 generates appropriate lens thickness information regarding the central thickness of the lens, the edge thickness of the lens, and the total thickness of the central thickness and the edge thickness which are optimal in a case where finishing processing is taken into consideration, with respect to the lens shape derived by the optical performance optimization calculation (S170).

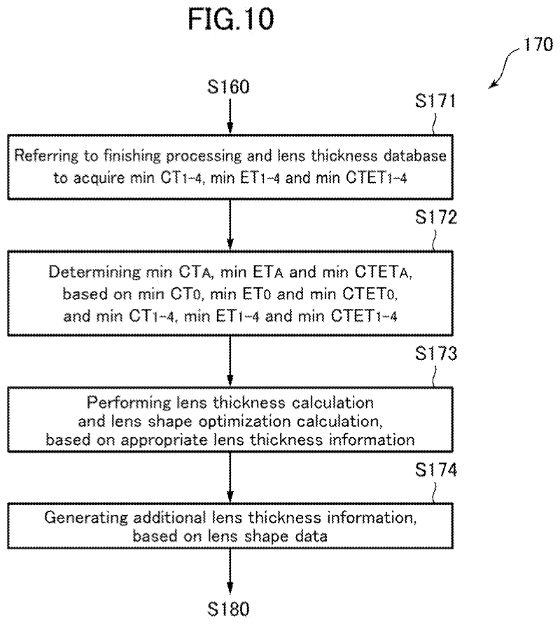

FIG. 10 is a flowchart showing a detailed flow of the shape optimization calculation step in the flowchart illustrated in FIG. 9. As shown in FIG. 10, in the shape optimization calculation step, firstly, the appropriate lens thickness information generation part 124 refers to the finishing processing and lens thickness database 126 to acquire the minimum central thicknesses min CT₁₋₄, the minimum edge thicknesses min ET₁₋₄ and the minimum total thicknesses min CTET₁₋₄ (S171). Specifically, firstly, the appropriate lens thickness information generation part 124 refers to the dyeing table of the finishing processing and lens thickness database 126 to acquire the minimum central thickness min CT₁, the minimum edge thickness min ET₁ and the minimum total thickness min CTET₁ which correspond to the combination of the type of dyeing material, the type of lens substrate and the type of dyeing method, designated based on the lens substrate information and the finishing processing information included in the prescription data.

Then, the appropriate lens thickness information generation part 124 refers to the hard coating table of the finishing processing and lens thickness database 126 to acquire the minimum central thickness min CT₂, the minimum edge thickness min ET₂ and the minimum total thickness min CTET₂ which correspond to the combination of the type of coating material, the type of lens substrate, and the type of coating method, designated based on the lens substrate information and the finishing processing information included in the prescription data.

Then, the appropriate lens thickness information generation part 124 refers to the functional film table of the finishing processing and lens thickness database 126 to acquire the minimum central thickness min CT₃, the minimum edge thickness min ET₃ and the minimum total thickness min CTET₃ which correspond to the combination of the type of functional film, the type of lens substrate, and the type of film formation method, designated based on the lens substrate information and the finishing processing information included in the prescription data.

Then, the appropriate lens thickness information generation part 124 refers to the frame table of the finishing processing and lens thickness database 126 to acquire the minimum central thickness min CT₄, the minimum edge thickness min ET₄ and the minimum total thickness min CTET₄ which correspond to the combination of the type of frame, the type of lens substrate, and the type of frame processing method, designated based on the lens substrate information and the finishing processing information included in the prescription data.

Subsequently, the appropriate lens thickness information generation part 124 determines the appropriate minimum central thickness min CT_{A}, the appropriate minimum edge thickness min ET_{A} and the appropriate minimum total thickness min CTET_{A}, based on the minimum central thicknesses min CT₁₋₄, the minimum edge thicknesses min ET₁₋₄ and the minimum total thicknesses min CTET₁₋₄ acquired in the above manner, and the minimum designated central thickness min CT₀, the minimum designated edge thickness min ET₀ and the minimum designated total thickness min CTET₀ (S172: appropriate lens thickness information generation step). The appropriate minimum central thickness min CT_{A}, the appropriate minimum edge thickness min ET_{A} and the appropriate minimum total thickness min CTET_{A} may be obtained by comparting the minimum central thicknesses min CT₁₋₄, the minimum edge thicknesses min ET₁₋₄ and the minimum total thicknesses min CTET₁₋₄ with the minimum designated central thickness min CT₀, the minimum designated edge thickness min ET₀ and the minimum designated total thickness min CTET₀, respectively, and adopting respective maximum values. The appropriate minimum central thickness min CT_{A}, the appropriate minimum edge thickness min ET_{A} and the appropriate minimum total thickness min CTET_{A} are generated as the appropriate lens thickness information.

Here, in a case where the minimum designated central thickness min CT₀, the minimum designated edge thickness min ET₀ and the minimum designated total thickness min CTET₀ are not included in the prescription data, respective minimum values of the minimum central thicknesses min CT₁₋₄, the minimum edge thicknesses min ET₁₋₄ and the minimum total thicknesses min CTET₁₋₄ may be generated as the appropriate lens thickness information. Although this embodiment has been described based on an example where respective minimum values of the central thickness, the edge thickness and the total of the central thickness and the edge thickness are recorded in each table, and a maximum value in each table is adopted as an appropriate value, the present disclosure is not limited thereto. For example, the system may be configured such that a function or a coefficient is recorded, and each of designated ones of the central thickness, the edge thickness and the total of the central thickness and the edge thickness is multiplied by the function or the coefficient.

Subsequently, based on the appropriate lens thickness information and the optical surface shape data derived by the optical performance optimization calculation, the thickness calculation and shape adjustment part 127 of the design data generation part 120 performs the lens thickness calculation and the lens shape optimization calculation to ensure the appropriate minimum central thickness min CT_{A}, the appropriate minimum edge thickness min ET_{A} and the appropriate minimum total thickness min CTET_{A} (S173: shape adjustment step).

Subsequently, the right and left lens thicknesses adjustment part 125 determines an additional lens thickness bases on the lens substrate information, the optical surface shape data and the appropriate lens thickness information. Specifically, the right and left lens thicknesses adjustment part 125 firstly calculates respective weights of right and left lenses, based on the lens substrate information, the optical surface shape data generated by the design data generation part 120. Then, the right and left lens thicknesses adjustment part 125 computes an additional lens thickness in conformity to a heavier one of the right and left lens, to generate additional lens thickness information (S174).

The design data is made up of the optical surface shape data, the lens thickness information and the additional lens thickness information generated in the above manner.

### Generation of Processing Data

The processing data generation part 130 generates processing data (S180). The processing data includes the finishing processing information, and processing correction design data.

The processing corrected design data is data for allowing the processing machine 400 to cut and grind a concave surface of a semifinished lens to form a finished lens, more specifically, data obtained by adding, to the designed data, a correction for reflecting a processing property of the lens on the design data.

In a case where the shape of a convex surface of a semifinished lens changes by a processing property of the lens when processing the lens, there arises a shift in lens power. Thus, a correction for cancelling out this shift based on the processing property data is added to the design data, and the resulting data is used as the processing data.

A spectacle lens manufacturer cuts and grinds the concave surface of the semifinished lens based on the processing data to form a finished lens.

### Generation of Inspection Criterion Data

The inspection criterion data generation part 140 generates data (inspection criterion data) serving as a criterion to be used when optical performance such as the aberration of a lens processed based on the processing data (finished lens) is inspected by the inspection device 450 provided in the processing machine 400 (S190).

The inspection criterion data is data serving as a criterion to be used when inspecting optical surface shape-related aberration of a finished lens, and is data generated separately from the design data and the processing data. Specifically, the inspection criterion data is data obtained by reflecting an actual surface shape of a semifinished lens on the design data.

The term “actual surface shape” means an actually measured shape of a convex surface of a semifinished lens, or the shape of a convex surface model statistically derived from a result of measurement of the semifinished lens.

When a semifinished lens is manufactured, a manufacturing error inevitably occurs due to polymerization shrinkage during casting, so that a finished lens is never manufactured accurately as per the design data. Further, since the processing data is obtained by reflecting the processing property on the design data, as mentioned above, a finished lens is never manufactured accurately as per the design data. Thus, if the design data or the processing data is used as criterion data for inspection of a finished lens, an accurate comparison cannot be performed. Therefore, in order to realize an accurate comparison, new data is generated by reflecting an actual surface shape of a semifinished lens on the design data, and used as the inspection criterion data.

### Output of Design Data

The data output part 150 outputs the design data to the LMS 200 (S200).

### Output of Processing Data

The data output part 150 outputs the processing data to the LMS 200 (S210).

### Output of Inspection Criterion Data

The data output part 150 outputs the inspection criterion data to the LMS 200 (S220).

### Cutting and Grinding of Semifinished Lens

The LDS 100 outputs, to the LMS 200, the processing data of a semifinished lens stored in a calculation result output file and a processing surface data file, and then the LMS 200 transmits this processing data to the CG 420 and the grinding machine 430 of the processing machine 400. Each of the CG 420 and the grinding machine 430 cuts/grinds the semifinished lens based on the processing data (S230).

### Finishing Processing

The lens shaped by cutting and grinding is subjected to finishing processing (S240). In this embodiment, the finishing processing includes dyeing of the lens, formation of a hard coating and/or a functional film on the lens, and processing of the lens to conform to a frame shape. The finishing processing information included in the processing data is displayed on the processing display 440. More specifically, the dyeing information regarding the type of lens dyeing, the hard coating information regarding the type of hard coating, the functional film information regarding the type of functional film and the frame information regarding the type of frame are displayed on the processing display 440. An engineer in charge of the above processing performs formation of a hard coating and/or a functional film on the lens, and processing of the lens to conform to a frame shape, while referring to the finishing processing information displayed on the processing display 440. In this way, a finished lens is produced.

### Inspection

The inspection device 450 measures optical performance of the finished lens, and compares the measured optical performance with the inspection criterion data received by the LMS 200 to inspect manufacturing accuracy of the finished lens (S250). Then, when the finished lens has a given level of manufacturing accuracy, the finishing processing is completed.

The above embodiment can bring out the following advantageous effects.

In the above embodiment, the appropriate lens thickness information generation part 124 generates the appropriate lens thickness information, and the thickness calculation and shape adjustment part 127 optimizes the lens shape based on the appropriate lens thickness information and the optical surface shape data, thereby generating the lens shape data. This makes it possible to suppress the occurrence of deformation and degradation in optical performance when subjecting a lens after shaping to finishing processing such as dyeing.

In the above embodiment, the finishing processing and lens thickness database 126 records therein the finishing processing and lens thickness data in which the finishing processing of the lens and the minimum lens thickness information indicative of a minimum value of the lens thickness are associated with each other, and the appropriate lens thickness information generation part 124 generates the appropriate lens thickness information based on the finishing processing and lens thickness data. This makes it possible to optimize the lens shape based on the appropriate lens thickness information corresponding to finishing processing to be applied to the lens, and more reliably suppress the occurrence of deformation and degradation in optical performance due to the finishing processing.

In the above embodiment, the LDS 100 comprises the right and left lens thicknesses adjustment part 125, and the right and left lens thicknesses adjustment part 125 adjusts thicknesses of right and left lens, based on the lens shape data, thereby generating adjusted lens thickness information regarding the adjusted lens thicknesses, so that it becomes possible to achieve a balance between weights of the right and left lens.

In the above embodiment, the finishing processing information comprises the dyeing information, the hard coating information, the functional film information and the frame information, so that it becomes possible to generate the appropriate lens thickness information, based on information about finishing processing which is more likely to cause deformation of the lens.

In the above embodiment, the appropriate lens thickness information comprises the appropriate central thickness information regarding an appropriate value of the central thickness of the lens, and the appropriate edge thickness information regarding an appropriate value of the edge thickness of the lens. The type of frame is likely to exert an influence on the appropriate edge thickness, and the type of dyeing or hard coating is likely to exert an influence on the appropriate central thickness. Thus, the above embodiment makes it possible to generate the appropriate central thickness while sufficiently taking into consideration the influence of each finishing processing.

The embodiment of the present disclosure will be outlined below.

According to one aspect of the present disclosure, there is provided a spectacle lens design system (LDS 100) for designing a spectacle lens. As shown in FIG. 3, the spectacle lens design system comprises: a prescription data acquisition part (110) to acquire prescription data which includes prescribed power information, and designated lens thickness information relating to finishing processing information regarding finishing processing after shaping of a spectacle lens; an optical surface calculation part (122) to calculate an optical surface shape based on the prescribed power information of the prescription data, thereby generating optical surface shape data; an appropriate lens thickness information generation part (124) to generate appropriate lens thickness information regarding a lens thickness appropriate for performing the finishing processing, based on the finishing processing information of the prescription data; and a thickness calculation and shape adjustment part (127) to adjust the spectacle lens based on the optical surface shape data and the appropriate lens thickness information, thereby generating lens shape data.

According to another aspect of the present disclosure, there is provided a spectacle lens design method for designing a spectacle lens. As shown in FIG. 9, the spectacle lens design method comprises: a prescription data acquisition step (S120) of acquiring prescription data which includes prescribed power information, and designated lens thickness information relating to finishing processing information regarding finishing processing after shaping of a spectacle lens; an optical surface calculation step (S160) of calculating an optical surface shape based on the prescribed power information of the prescription data, thereby generating optical surface shape data; an appropriate lens thickness information generation step (S172) of generating appropriate lens thickness information regarding a lens thickness appropriate for performing the finishing processing, based on the finishing processing information of the prescription data; and a shape adjustment step (S173) of adjusting a lens shape based on the optical surface shape data and the appropriate lens thickness information, thereby generating lens shape data.

### LIST OF REFERENCE SIGNS

1: ordering and processing system
3: network
60: computer
61: CPU
62: RAM
63: ROM
64: HDD
65: operation unit-related output I/F
66: operation unit-related input I/F
67: operation unit-related input I/F
68: system bus
71: operation display unit
72: operation input unit
100: LDS
110: prescription data acquisition part
115: processing property acquisition part
116: processing property database
120: design data generation part
121: initial value calculation part
122: optical surface calculation part
123: shape optimization part
124: appropriate lens thickness information generation part
125: right and left lens thicknesses adjustment part
126: lens thickness database
127: shape adjustment part
130: processing data generation part
140: inspection criterion data generation par
150: data output part
200: LMS
300: terminal device
400: processing machine
410: blocker
430: grinding machine
440: processing display
450: inspection device

1. A spectacle lens design system for designing a spectacle lens, comprising:
a prescription data acquisition part to acquire prescription data which includes prescribed power information, and designated lens thickness information relating to finishing processing information regarding finishing processing after shaping of a spectacle lens;
an optical surface calculation part to calculate an optical surface shape based on the prescribed power information of the prescription data, thereby generating optical surface shape data;
an appropriate lens thickness information generation part to generate appropriate lens thickness information regarding a lens thickness appropriate for performing the finishing processing, based on the finishing processing information of the prescription data; and
a shape adjustment part to adjust the spectacle lens based on the optical surface shape data and the appropriate lens thickness information, thereby generating lens shape data.

2. The spectacle lens design system according to claim 1, wherein the appropriate lens thickness information generation part is configured to, based on finishing processing and lens thickness data in which finishing processing of the lens and minimum lens thickness information indicative of a minimum value of the lens thickness are associated with each other, acquire the minimum lens thickness information corresponding to the finishing processing information of the prescription data, and, based on the acquired minimum lens thickness information, generate the appropriate lens thickness information.

3. The spectacle lens design system according to claim 1, which further comprises a right and left lens thicknesses adjustment part to adjust right and left lens thicknesses, based on the lens shape data, thereby generating adjusted lens thickness information regarding the adjusted lens thicknesses.

4. The spectacle lens design system according to claim 1, wherein the finishing processing information regarding the finishing processing of the lens comprises at least one of the group consisting of: dyeing information regarding lens dyeing; hard coating information regarding a hard coating; functional film information regarding a functional film; and frame information regarding a frame.

5. The spectacle lens design system according to claim 1, wherein the appropriate lens thickness information comprises at least appropriate central thickness information regarding an appropriate value of a central thickness of the lens, and appropriate edge thickness information regarding an appropriate value of an edge thickness of the lens.

6. A spectacle lens design method for designing a spectacle lens, comprising:
a prescription data acquisition step of acquiring prescription data which includes prescribed power information, and designated lens thickness information relating to finishing processing information regarding finishing processing after shaping of a spectacle lens;
an optical surface calculation step of calculating an optical surface shape based on the prescribed power information of the prescription data, thereby generating optical surface shape data;
an appropriate lens thickness information generation step of generating appropriate lens thickness information regarding a lens thickness appropriate for performing the finishing processing, based on the finishing processing information of the prescription data; and
a shape adjustment step of adjusting a lens shape based on the optical surface shape data and the appropriate lens thickness information, thereby generating lens shape data.

7. A spectacle lens design program for causing a computer to execute the spectacle lens design method according to claim 6.
